(19) United States
(12) Patent Application Publication
(10) Pub. No.: US 2008/0113508 A1
(43) Pub. Date: May 15, 2008

(54) Method of fabricating metal interconnects using a sacrificial layer to protect seed layer prior to gap fill

(76) Inventors: Rohan N. Akolkar, Hillsboro, OR (US); Florian Gstrein, Portland, OR (US); Valery M. Dubin, Portland, OR (US); Daniel J. Zierath, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/598,889

(22) Filed: Nov. 13, 2006

(51) Int. Cl. H01L 21/44

(52) U.S. Cl. 438/687

(57) ABSTRACT

Disclosed are embodiments of a method of forming metal interconnects using a sacrificial layer to protect a seed layer prior to metal gap fill. The sacrificial layer can prevent oxidation of the seed layer and perhaps oxygen migration to an underlying barrier layer. Other embodiments are described and claimed.

### FIELD OF THE INVENTION

The disclosed embodiments relate generally to the manufacture of integrated circuit devices, and more particularly to methods of fabricating metal interconnects using a sacrificial layer to protect a seed layer prior to metal deposition.

### BACKGROUND OF THE INVENTION

An integrated circuit (IC) device typically comprises a semiconductor die in which circuitry has been formed, this circuitry including a collection of circuit elements such as transistors, diodes, capacitors, resistors, etc. To provide electrical connections between the die and a next-level component (e.g., a package substrate), an interconnect structure is formed over a surface of the die. The interconnect structure may comprise a number of levels of metallization, each layer of metallization separated from adjacent levels by a layer of dielectric material and interconnected with the adjacent levels by vias. The dielectric layers of the interconnect structure are often each referred to as an “interlayer dielectric” (or “ILD”). The metallization on each layer comprises a number of interconnects (e.g., conductive traces) that may route signal, power, and ground lines to and from the circuitry formed on the die.

The conductors of any given metallization layer typically comprise a pattern of trenches and vias, or other features, that are formed in the dielectric layer. The trenches and vias are filled with an electrically conductive material, such as copper. To fill these features with metal, a relatively thin seed layer may be first deposited by, for example, a chemical vapor deposition (CVD) process or physical vapor deposition (PVD) process. After seed layer formation, metal is then deposited in the unfilled portions, or gaps, that remain in the trenches and vias to completely fill these features. This gap fill process may be performed using an electroplating process, in which the metal is grown on the underlying seed layer. After gap fill, a planarization process, such as chemical mechanical polishing (CMP), may be carried out to remove any excess metal material. Also, a barrier layer may be deposited prior to seed layer deposition to prevent metal migration into the surrounding dielectric material.

Semiconductor device manufacturers are continually shrinking feature sizes on the device layer (e.g., the size of transistors and other circuit elements), which may also lead to a corresponding increase in circuit density. As a result of the increased number of more closely spaced circuit elements in the device layer, features sizes within the interconnect structure (e.g., the sizes of trenches and vias, or other features, in the metallization layers) may also decrease. At the same time, the thickness of the seed layer (e.g., a seed layer for copper deposition) that is deposited during metallization of any given layer in the interconnect structure is limited by the width of features on that layer, because a “pinching” effect will occur at the opening of a trench or via due to overhang of the seed material. This pinching effect will close off the trench or via, and prevent further deposition of metal (e.g., electroplated copper) within the feature. However, if a seed layer is too thin, bulk oxidation of the seed layer can occur prior to gap fill. If the seed layer is allowed to oxidize through it's thickness, oxygen diffusion to the underlying barrier layer can occur. Adhesion of a metal (e.g., copper) to an oxidized barrier layer (e.g., tantalum oxide) may be poor, which can lead to agglomeration of the metal on the feature side walls and, hence, to voids in the metal structure. Such voids in the metal interconnects may result in decreased reliability and/or device failure.

### BRIEF DESCRIPTION OF THE DRAWINGS

FIG. 1 is a block diagram illustrating an embodiment of a method of fabricating metal interconnects using a sacrificial layer to protect a seed layer.

FIGS. 2A-2I are schematic diagrams illustrating embodiments of the method shown in FIG. 1.

FIG. 3 is a schematic diagram illustrating an embodiment of an integrated circuit die that may be formed according to any of the disclosed embodiments.

### DETAILED DESCRIPTION OF THE INVENTION

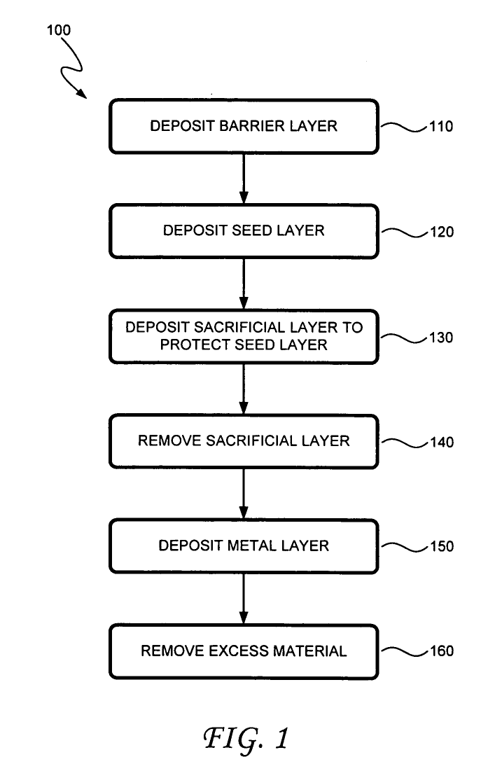

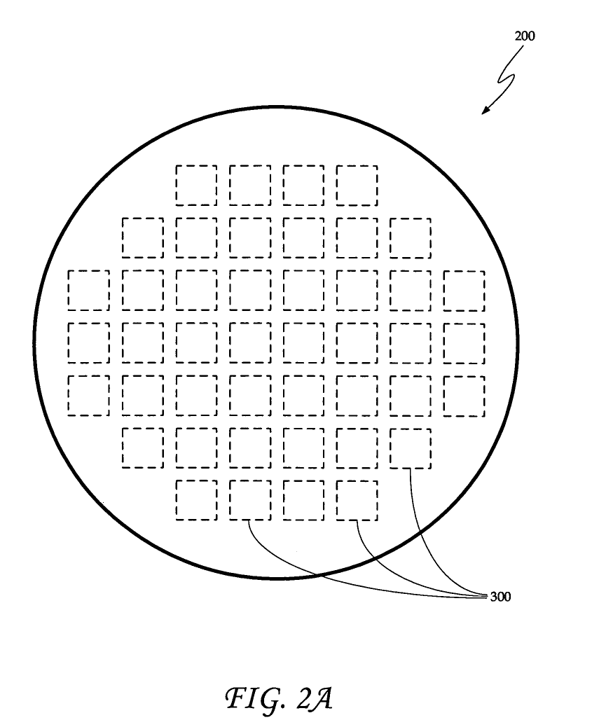

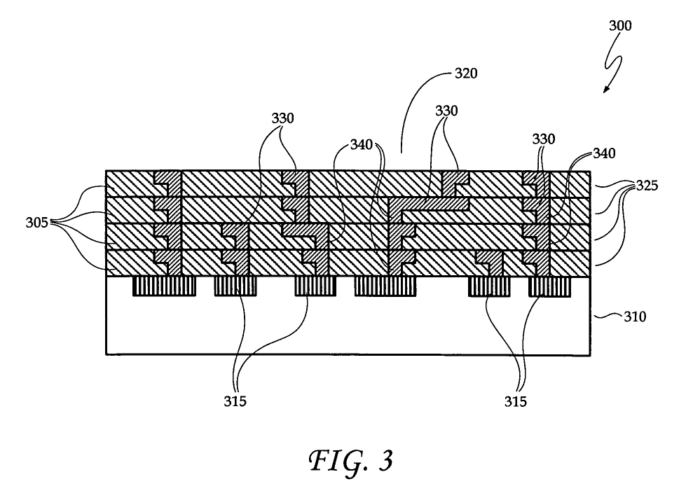

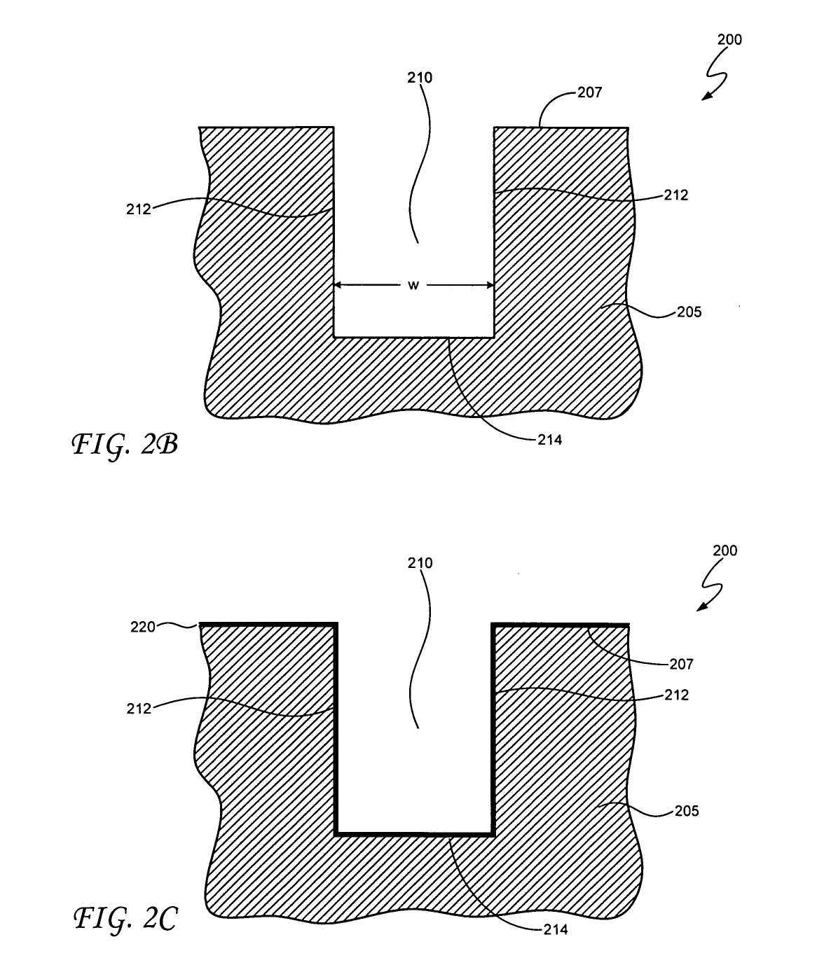

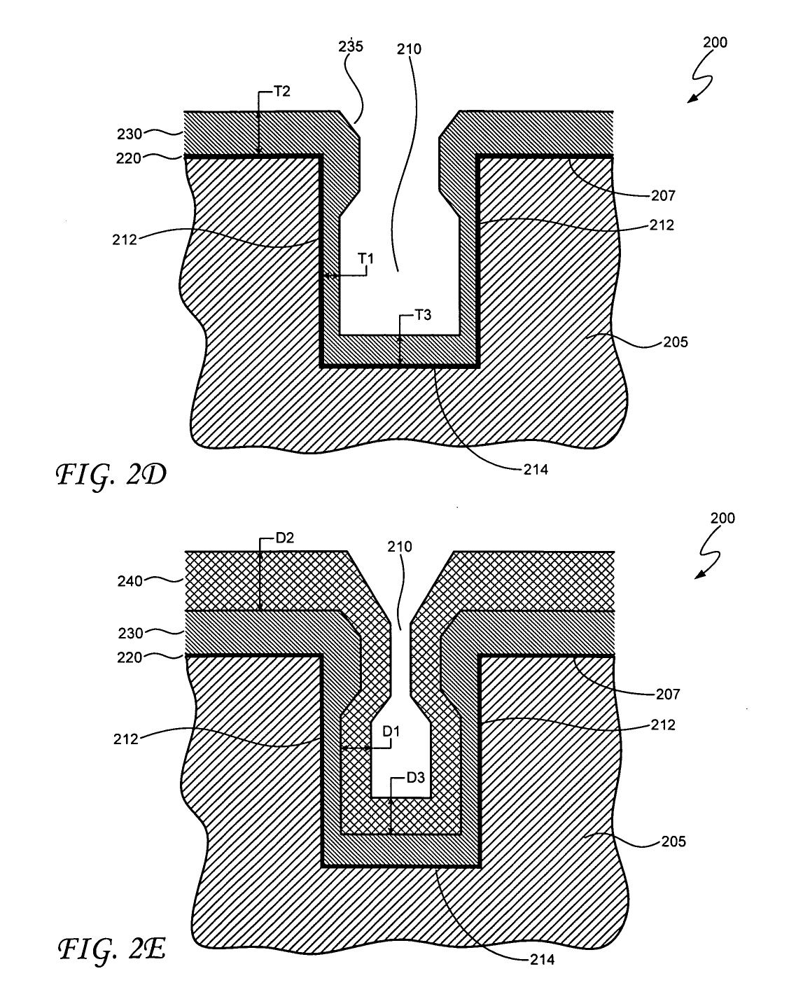

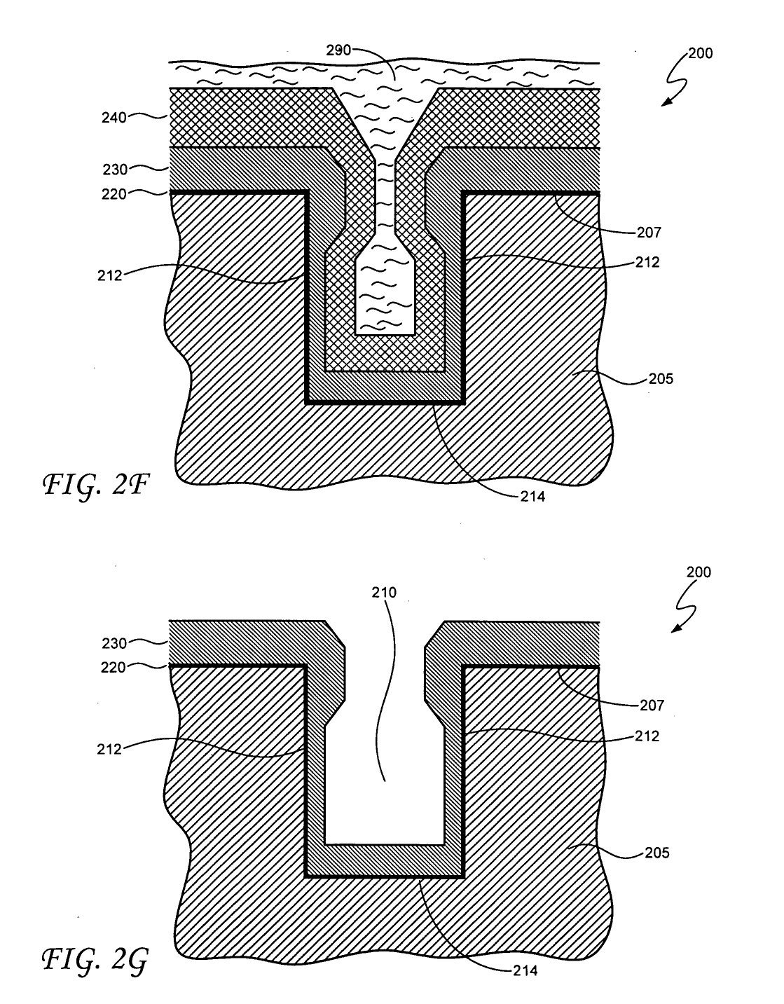

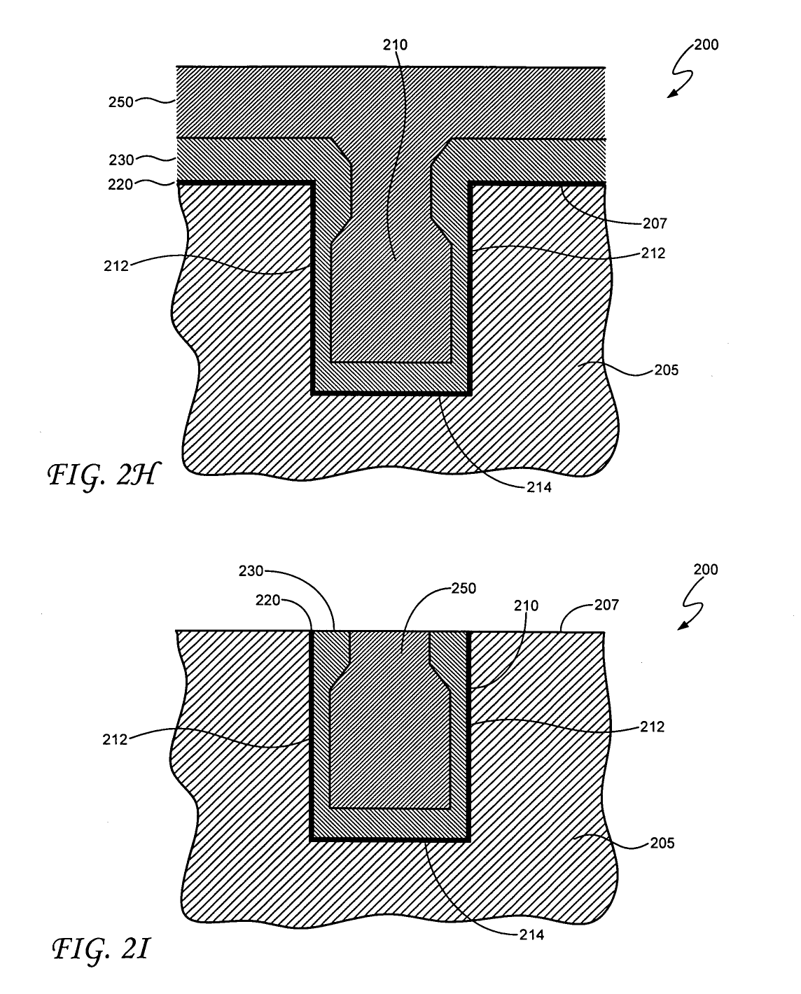

Illustrated in FIG. 1 is an embodiment of method 100 of fabricating metal interconnects using a sacrificial layer. The sacrificial layer is disposed over a seed layer, and this sacrificial layer can prevent oxidation of the seed layer and, hence, diffusion of oxygen to an underlying barrier layer, as well as agglomeration of metal on the feature side walls. Embodiments of the method 100 are further illustrated in FIGS. 2A through 2H, and reference should be made to these figures as called out in the text below.

Referring first to FIGS. 2A and 2B, a substrate 200 is shown. The substrate 200 may comprise any substrate upon which a trench or other feature is formed that will ultimately be filled with a metal. In one embodiment, the substrate 200 comprises a semiconductor wafer (e.g., Si, SOI, GaAs, etc.) upon which integrated circuitry for a number of die 300 has been formed (see FIG. 2A), and wafer 200 is ultimately cut into these separate die. An interconnect structure will be formed over the device layer of this wafer (for each die 300), and this interconnect structure may include a number of levels of metallization. Each layer of metallization is separated from adjacent levels by a layer of dielectric material, and each layer is interconnected with the adjacent levels by vias. The metallization on each layer may comprise a number of conductors that may route signal, power, and ground lines to and from the circuitry formed on the wafer. For ease of illustration, in FIG. 2B—as well as FIGS. 2C through 2I—only a portion of the substrate 200 is shown (in cross-section). More specifically, a portion of a dielectric layer 205 is shown, and this dielectric layer may comprise a layer in the interconnect structure that is formed over the device layer of the substrate 200.

With reference to FIG. 2B, a feature 210 has been formed in the dielectric layer 205 of substrate 200. The feature 210 may comprise a trench, via, as well as any combination of these and/or other features. In one embodiment, the trench 210 comprises part of a pattern of trenches and vias (and/or other features) that will form the conductors of one layer in the interconnect structure. For ease of explanation, the feature 210 will be referred to below as a trench; however, it should be understood that the disclosed embodiments may be applied to any feature (or combination of features) upon which a seed layer is to be deposited for subsequent metallization. The trench may be formed by any suitable process or combination of processes (e.g., photolithography followed by an etching process, etc.). In one embodiment, the trench 210 (or via or other feature) has a width (w) of up to 50 nm, and in a further embodiment, the trench has a width (w) of 30 nm or less. In yet another embodiment, the trench 210 has a width (w) of approximately 20 nm.

At this juncture, it should be noted that the disclosed embodiments are described in the context of a single trench formed in one dielectric layer of an interconnect structure. However, it should be understood that the disclosed embodiments are not so limited in application and, further, that the disclosed embodiments may find use with any structure having a feature that is to be filled with a metal. Furthermore, although a single trench in one dielectric layer is shown in the figures, it should be understood that the disclosed embodiments will typically be performed at the wafer level, and that such a wafer may include an interconnect structure for several hundred die, with the interconnect structure of each die perhaps containing thousands of conductors.

Turning now to block 110 in FIG. 1, in one embodiment, a barrier layer is deposited over the side walls of a feature that has been formed in a substrate. Deposition of the barrier layer is illustrated in FIG. 2C, where a barrier layer 220 has been deposited over the bottom 214 and side walls 212 of the trench 210, as well as over an upper surface 207 of the substrate 200 (e.g., the upper surface of a previously patterned dielectric layer 205 that is to be metallized). As suggested above, the trench 210 will ultimately be filled with a metal, and the barrier layer 220 may comprise any material capable of preventing or at least partially inhibiting the migration of metal into the surrounding dielectric layer 205. By way of example, the barrier layer may comprise Ta, TaN, TaSi, TaSiN, W, WN, Ti, TiN, Mo, MoN, Nb, NbN, or Ir, as well as combinations of these and other materials. Further, the barrier layer 220 may be deposited using any suitable process. For example, the barrier layer may be deposited by chemical vapor deposition (CVD), physical vapor deposition (PVD), or atomic layer deposition (ALD). Also, the barrier layer 220 may have any suitable thickness, and in one embodiment this layer has a thickness of between 10 and 100 Angstroms (on at least the side walls 212 of the trench 210).

Referring to block 120 in FIG. 1, a seed layer is deposited over the barrier layer. This is further illustrated in FIG. 2D, where a seed layer 230 has been deposited over the barrier layer 220. The seed layer 230 may comprise any material upon which a subsequent layer of a metal (or other electrically conductive material) can be deposited or grown. For example, in one embodiment, the trench 210 will ultimately be filled with copper (Cu), and the seed layer 230 comprises copper or a copper alloy. However, it should be understood that other materials can function as a seed layer for subsequent copper deposition and, further, that trench 210 may be filled with other materials besides copper (which may require alternative seed layer materials). The seed layer 230 may be deposited using any suitable process, and in one embodiment a PVD process is employed to form the seed layer. It should, however, be understood that other processes (e.g., CVD, ALD, electroplating, electroless plating, etc.) may be used for seed layer formation.

The seed layer 230 may have any suitable thickness. Typically, as a result of the deposition process, the seed layer 230 will have a greater thickness on the upper surface 207 of substrate 200 than on the side walls 212 of the trench 210. In some embodiments, the thickness (T1) on the side walls 212 is approximately ten percent of the field thickness (T2) that is deposited on the upper substrate surface 207. The thickness (T3) on the bottom 214 of trench 210 may also be greater than on the side walls 212. Note also that a pinching effect may occur at the opening of the trench 210 due to overhang (see reference numeral 235) of the seed layer material 230. Due to this pinching effect, seed layer deposition is halted at some point prior to closing off of the trench 210, as such a condition would prevent further deposition of metal within the trench. According to one embodiment—which may occur where the trench 210 has a width (w) of 50 nm or less—the thickness (T1) of the seed layer 230 on the side walls 212 is between 10 and 30 Angstroms (and the thickness (T2) on the upper substrate 207 between 100 and 300 Angstroms). Depending upon the width (w) of trench 210, the seed layer material being deposited, and the deposition process (and perhaps other factors), the seed layer 230 may have any other suitable thicknesses on the side walls 212 and upper substrate surface 207.

If the seed layer 230 is sufficiently thin, this layer may be susceptible to oxidation through it's full thickness. Such bulk oxidation of the seed layer 230 could lead to oxygen migration to the barrier layer 220 and, further, to oxidation of the barrier layer material. To prevent, or at least minimize, oxidation of the seed layer 230, a sacrificial layer is deposited over the seed layer, as set forth in block 130. This is further illustrated in FIG. 2E, which shows a sacrificial layer 240 that has been deposited over the seed layer 230. In one embodiment, the sacrificial layer 240 comprises a material that forms a thin oxide layer (e.g., the material is capable of self passivation). In another embodiment, the sacrificial layer 240 comprises a material that is amenable to removal by a process that does not remove the underlying seed layer 230, or a material that is amenable to removal by a process that removes the sacrificial material at a much greater rate than removal of the underlying seed layer 230. In a further embodiment, the sacrificial layer 240 comprises a material having an electrochemical reduction potential. In yet another embodiment, the sacrificial material layer 240 comprises a material that can function as an oxygen diffusion barrier, or that can otherwise prevent (or minimize) oxidation of the underlying seed layer 230. According to one embodiment, the sacrificial layer 240 comprises aluminum (Al). However, it should be understood that the disclosed embodiments are not limited to use of aluminum as the sacrificial layer and, further, that other materials may be suitable for this layer, including Ta, Ti, Mg, Mn, and metal silicides, as well as combinations of these and/or other materials.

The sacrificial layer 240 may be deposited using any suitable process. For example, the sacrificial layer may be deposited using CVD, PVD, ALD, electroplating, or electroless plating, as well as any other suitable process or combination of processes. Also, the sacrificial layer 240 may have any suitable thickness. In one embodiment, the sacrificial layer 240 has a field thickness (D2) over the upper surface 207 of between 100 and 1,000 Angstroms. Again, as a result of the deposition process, the thickness (D1) over the trench side walls 212 may be less than the field thickness (D2), and the thickness (D3) over the trench bottom 214 may also be less than the field thickness (but perhaps greater than the thickness over the side walls).

As noted above, the trench 210 will ultimately be filled in with a metal (e.g., copper) to create an interconnect (e.g., a conductive trace or via) within the dielectric layer 205. At some time prior to metal deposition, the sacrificial layer 240 is removed, which is set forth in block 140 of FIG. 1. However, prior to metal deposition, the sacrificial layer 240 functions to protect the underlying seed layer 230 (e.g., to prevent or minimize oxidation of the seed layer and, hence, to prevent oxygen diffusion to the barrier layer 220).

Removal of the sacrificial layer 240 is further illustrated in FIG. 2F, wherein in one embodiment the sacrificial layer 240 is being etched in a liquid medium 290. The etching medium 290 may comprise, for example, potassium hydroxide (KOH), sodium hydroxide (NaOH), or tetramethylammonium hydroxide (TMAH). In one embodiment, the etch solution 290 has a pH of between 9 and 11. In another embodiment, the etching medium 290 further includes a reducing agent, and this reducing agent is intended to lower the electrochemical potential of the etching solutions such that the solution preferentially removes the sacrificial material (e.g., aluminum) without removing and/or oxidizing the underlying seed layer (e.g., copper). Examples of suitable reducing agents may include glyoxylic acid, formaldehyde, and ammonia borane. The substrate 200 may be exposed to the etching solution 290 until full removal of the sacrificial layer 240 has been achieved, as shown in FIG. 2G (although trace amounts of the sacrificial material may remain on the surfaces of the seed layer 230).

As set forth in block 150, a metal layer is deposited to fill the trench or other feature (or features). This is illustrated in FIG. 2H, where a metal layer 250 has been deposited to fill the trench 210. In one embodiment, the metal layer 250 comprises copper; however, this metal layer may comprise any other electrically conductive material (e.g., silver, aluminum, etc.). Any suitable process may be employed to deposit the metal layer 250, and in one embodiment the metal layer is deposited using an electroplating process. For electroplating, any suitable plating chemistry can be used, and in one embodiment the plating solution has a pH of between 1 and 3. By way of example, the plating chemistry may include 10 to 50 grams/liter (g/L) copper sulfate, 10 to 20 g/L sulfuric acid, and one or more plating additives. The plating additive (or additives) may be present in the etching solution at a level between approximately 10 and 100 ppm (parts-per-million), and examples of additives include polymers (e.g., polyethylene glycol, polypropylene glycol, and their mixtures), disulfides, and quaternary nitrogen containing surfactants.

Typically, the etching bath (for removal of sacrificial layer 240) and the plating bath (for deposition of metal layer 250) are separate (e.g., separate baths on separate tools, separate baths on the same tool, etc.). However, in one embodiment, etching of the sacrificial layer 240 and deposition of the metal layer 250 are performed in the same bath. For example, where the sacrificial layer 240 comprises aluminum and the metal layer 250 copper, removal of the sacrificial layer may be performed in an alkaline electroless Cu plating bath which etches the aluminum first and then deposits a layer of copper on top of the underlying seed layer. By way of example, the electroless plating chemistry may comprise 1 to 5 g/L of copper sulfate, 10 to 50 g/L of a complexing agent, 1 to 10 g/L of a reducing agent in KOH or NaOH adjusted to a pH of between approximately 9 and 12. The electroless plating solution may also contain one or more additives.

Referring back to FIG. 1, excess material may be removed from the substrate, as set forth in block 160. This is further illustrated in FIG. 2I, where excess material has been removed from the upper surface 207 of substrate 200, with portions of the metal, seed, and barrier layers 250, 230, 220, respectively, remaining in the trench 210 (and perhaps trace amounts of the sacrificial layer 240). Any suitable process may be used to remove excess material from the substrate 200. In one embodiment, for example, the excess material is removed by chemical-mechanical polishing (CMP); however, other processes may also be suitable.

With continued reference to FIG. 21, in one embodiment the seed layer 230 may have a thickness (T1) on the trench side walls 212 of between 10 and 30 Angstroms, as noted above. A metal layer of this thickness (e.g., a copper layer) has the potential to undergo bulk oxidation, which could allow oxygen to migrate to the barrier layer 220. Should portions of the barrier layer 220 oxidize, agglomeration of metal (e.g., copper) on the trench side walls could occur as a result of poor adhesion to the oxidized barrier layer, which could lead to voids and perhaps decreased reliability. However, in the disclosed embodiments, the sacrificial layer 240 protects the seed layer 230 (and also the barrier layer 220) prior to metal deposition and, therefore, the deleterious effects described above can be avoided or at least minimized.

Turning now to FIG. 3, illustrated is an embodiment of an integrated circuit die 300, which may be formed according to the disclosed embodiments. The die 300 comprises a semiconductor substrate 310, and circuitry 315 has been formed on a device layer of this substrate. The circuitry 315 may include a number of circuit elements (e.g., transistors, diodes, capacitors, resistors, etc.), as well as various signal lines that interconnect these elements. The substrate 310 may comprise any suitable semiconductor material, such as silicon (Si), silicon-on-insulator (SOI), gallium arsenide (GaAs), etc.

Disposed on the substrate 310 is an interconnect structure 320. The interconnect structure 320 includes a number of levels of metallization 325. Each level 325 comprises a number of interconnects, including conductive traces 330 and conductive vias 340. Each level of metallization is also disposed within and/or supported by a layer of dielectric material 305. The interconnects of any given metallization layer 325 are separated from the conductors in adjacent levels by one of the dielectric layers 305, and adjacent levels of metallization are electrically interconnected by the vias 340. The interconnects—e.g., traces 330 and vias 340—may comprise any suitable conductive material, such as copper, aluminum, gold (Au), silver (Ag), or alloys of these and/or other materials. The dielectric layers 305 may comprise any suitable dielectric or insulating material, such as silicon dioxide (SiO₂), SiOF, carbon-doped oxide (CDO), a glass, or a polymer material. In one embodiment, the conductors 330 and vias 340 (or other interconnects) are formed according to any of the embodiments described above, wherein a sacrificial layer may be deposited over a seed layer prior to metal deposition.

As the reader will appreciate, only a limited number of circuit elements 315, conductors 330, and vias 340 are shown in FIG. 3 for ease of illustration. However, as the reader will appreciate, the integrated circuitry 315 formed on substrate 310 may, in practice, includes tens of millions, or even hundreds of millions, of individual circuit elements and, further, that the interconnect structure 320 may include several hundred or even thousands of conductors 330 and/or vias 340 (or other interconnects). Thus, it should be understood that FIG. 3 is a simplified schematic representation of an integrated circuit die 300 that is presented merely as an aid to understanding the disclosed embodiments and, further, that no unnecessary limitations should be drawn from this schematic representation.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. A method comprising:
depositing a barrier layer over a surface of a substrate and over side walls of a trench or via formed in the substrate;
depositing a copper seed layer over the barrier layer;
depositing a sacrificial aluminum layer over the copper seed layer to prevent oxidation of the copper seed layer;
removing the sacrificial aluminum layer using an etching solution including a reducing agent; and
electroplating a layer of copper over the copper seed layer to fill the trench or via.

2. The method of claim 1, wherein the etching solution comprises a substance selected from a group consisting of potassium hydroxide, sodium hydroxide, and tetramethylammonium hydroxide.

3. The method of claim 1, wherein the reducing agent comprises a substance selected from a group consisting of glyoxylic acid, formaldehyde, and ammonia borane.

4. The method of claim 1, wherein the barrier layer comprises a material selected from a group consisting of Ta, TaN, TaSi, TaSiN, W, WN, Ti, TiN, Mo, MoN, Nb, NbN, and Ir.

5. The method of claim 1, wherein the substrate comprises a dielectric material.

6. The method of claim 1, wherein the trench or via has a width dimension of 50 nm or less.

7. The method of claim 1, wherein the etching solution has a pH of between approximately 9 and 11, and wherein the electroplating of the copper layer is performed in a plating bath having a pH of between approximately 1 and 3.

8. A method comprising:
forming a feature in a dielectric layer of an interconnect structure formed on a semiconductor substrate;
forming a seed layer on walls of the feature;
depositing a sacrificial layer over the seed layer to prevent oxidation of the seed layer;
removing the sacrificial layer using an etching solution including a reducing agent; and
electroplating a layer of metal over the seed layer.

9. The method of claim 8, wherein the metal layer comprises copper.

10. The method of claim 9, wherein the seed layer comprises copper.

11. The method of 10, wherein the sacrificial layer comprises aluminum.

12. The method of claim 11, wherein the etching solution comprises a substance selected from a group consisting of potassium hydroxide, sodium hydroxide, and tetramethylammonium hydroxide.

13. The method of claim 12, wherein the reducing agent comprises a substance selected from a group consisting of glyoxylic acid, formaldehyde, and ammonia borane.

14. The method of claim 8, further comprising depositing a barrier layer over the walls of the feature prior to formation of the seed layer, wherein the seed layer is formed over the barrier layer.

15. The method of claim 14, wherein the barrier layer comprises a material selected from a group consisting of Ta, TaN, TaSi, TaSiN, W, WN, Ti, TiN, Mo, MoN, Nb, NbN, and Ir.

16. The method of claim 8, wherein the etching solution has a pH of between approximately 9 and 11, and wherein the electroplating of the metal layer is performed in a plating bath having a pH of between approximately 1 and 3.

17. The method of claim 8, wherein the feature comprises a trench or via.

18. The method of claim 8, wherein the feature has a width dimension of 30 nm or less.
